(19) United States
(12) Patent Application Publication
(10) Pub. No.: US 2008/0318412 A1
(43) Pub. Date: Dec. 25, 2008

(54) METHOD OF MANUFACTURING A SEMICONDUCTOR DEVICE

(75) Inventor: Yoshihisa IBA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/138,964

(22) Filed: Jun. 13, 2008

(30) Foreign Application Priority Data
Jun. 19, 2007 (JP) 2007-161021

(51) Int. Cl. H01L 21/4763

(52) U.S. Cl. 438/627; 257/E21.483

(57) ABSTRACT

A method of manufacturing a semiconductor device has forming an interlayer insulating film over a wiring layer, forming an opening in the interlayer insulating film, performing a first plasma treatment using a gas including hydrogen or ammonia, performing a second plasma treatment with a gas including fluorocarbon after the first plasma treatment.

### CROSS-REFERENCE TO RELATED APPLICATIONS

This application is based upon and claims the benefit of priority from the prior Japanese Patent Application No. 2007-161021, filed on Jun. 19, 2007, the entire contents of which are incorporated herein by reference.

### BACKGROUND

The present invention relates to a method of manufacturing a semiconductor device, and particularly to a method of manufacturing a semiconductor device including an interlayer insulating film and a wiring formed over a substrate.

Increasing speed and power consumption reduction of large scale integrated circuits (LSIs) have recently been advanced with the progress of miniaturization. In order to improve these characteristics, an interlayer insulating film of a low-dielectric-constant material and a multilayer wiring layer including a copper wiring layer are used. In addition, there are studies on the use of a material in which oxygen of silicon oxide is partially substituted by a hydroxyl group, a methyl group, or another alkyl group or alkoxyl group, or an organic material (hereinafter referred to as a SiCOH material) as the interlayer insulting film.

In a process of manufacturing a semiconductor device having the above-described configuration, the interlayer insulating film is etched to form, as a via hole, an opening hole which reaches the Cu wiring layer. In the etching process, the etching product is deposited over the Cu wiring layer at the bottom of the opening hole. The etching product causes a defect in contact between a plug formed in the via hole and the Cu wiring layer, thereby decreasing the reliability of the semiconductor device.

In order to remove the etching product, a plasma treatment with a gas containing hydrogen is known.

However, a damage layer is formed by the plasma treatment with the hydrogen-containing gas over the wall surface of the interlayer insulating film. Further, the damage layer decrease reliability of the semiconductor device.

### SUMMARY

According to an aspect of the present invention a method of manufacturing a semiconductor device has forming an interlayer insulating film over a wiring layer, forming an opening in the interlayer insulating film, performing a first plasma treatment using a gas including hydrogen or ammonia, performing a second plasma treatment with a gas including fluorocarbon after the first plasma treatment.

### BRIEF DESCRIPTION OF THE DRAWINGS

FIGS. 1A to 1D are sectional views showing a process of manufacturing a semiconductor device according to an embodiment of the present invention;

FIGS. 2A to 2C are sectional views showing a change in state of an interlayer insulating film according to an embodiment of the present invention;

FIGS. 3A to 3H are sectional views showing a process of manufacturing a semiconductor device including a multilayer wiring structure according to an embodiment of the present invention; and

FIG. 4 is a graph showing the dependency of the number of defects in the plug based on the time of a plasma treatment with a gas containing hydrogen according to an embodiment of the present invention.

### DESCRIPTION OF THE PREFERRED EMBODIMENTS

An embodiment of the present invention will be described in detail below with reference to the drawings. However, the technical scope of the present invention is not limited to the embodiment.

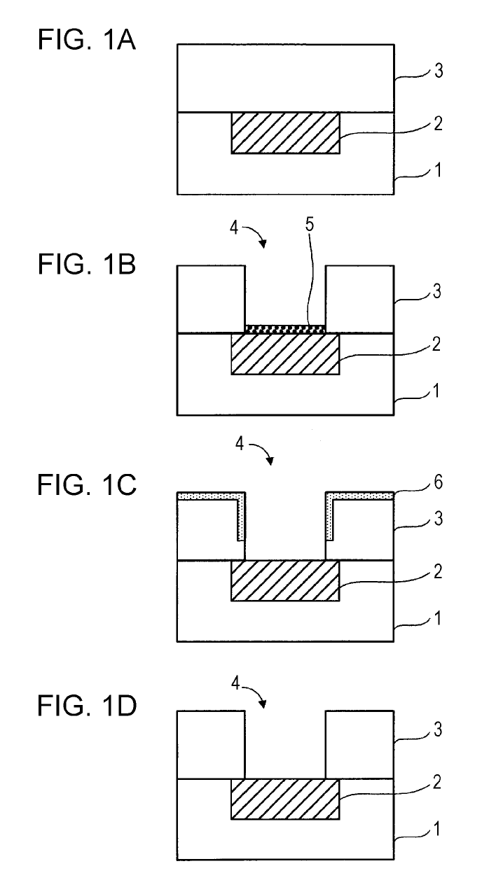

FIGS. 1A to 1D are sectional views showing a process of manufacturing a semiconductor device according to an embodiment of the present invention.

As shown in FIG. 1A, a wiring layer 2 is formed in a substrate 1. The substrate 1 represents an insulating film formed over a semiconductor substrate. Then, a low-dielectric-constant insulating film 3 having a methyl group is formed over the substrate 1 and the wiring layer 2.

The low-dielectric-constant insulating film 3 serving as an interlayer insulating film has a dielectric constant value lower than that of silicon oxide, preferably a dielectric constant value of about 2.5 or less.

As shown in FIG. 1B, an opening 4 is formed by etching the low-dielectric-constant insulating film 3. In this step, atoms of the etched low-dielectric-constant insulating film 3 are deposited over the wiring layer 2 at the bottom of the opening 4 to form an etching product 5. The etching product 5 causes a defect in contact between the wiring layer 2 and the plug to be formed in the opening 4 in a subsequent step.

As shown in FIG. 1C, in order to remove the etching product 5, a plasma treatment is performed with a gas containing hydrogen or ammonia. The plasma treatment with a gas containing hydrogen or ammonia may be used for reducing a metal oxide formed over the surface of the wiring layer 2. In this sense, the plasma treatment is preferably performed using a reducing gas. Consequently, a damage layer 6 is formed over the low-dielectric-constant layer 3. The damage layer 6 causes a decrease in reliability of a semiconductor device.

As shown in FIG. 1D, a plasma treatment with a gas containing fluorocarbon is further performed. As a result, the damage layer 6 can be removed.

Although not shown in the drawing, in succession to the step shown in FIG. 1D, a plug is formed in the opening 4 to form a semiconductor device having a wiring structure.

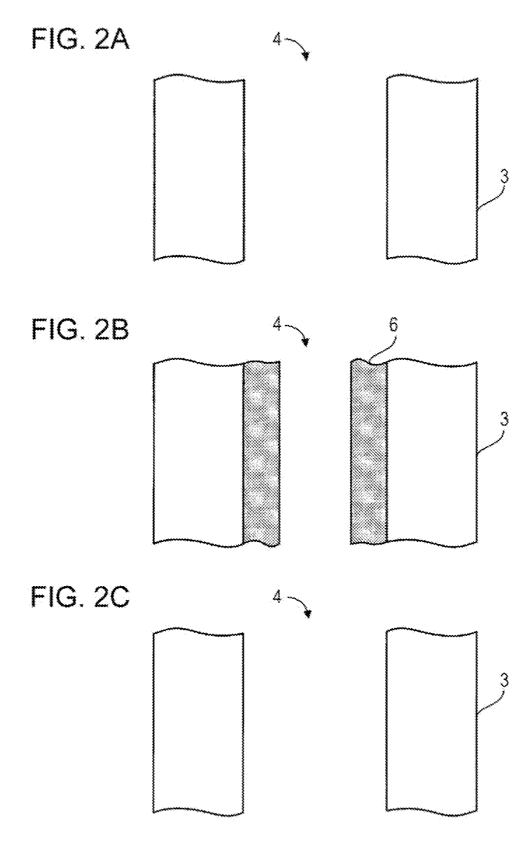

Next, a change in state of the wall surface of the low-dielectric-constant insulating film 3 will be described in detail with reference to FIGS. 2A to 2C.

FIGS. 2A to 2C are sectional views showing a change in state of the interlayer insulating film according to this embodiment of the present invention.

FIG. 2A shows the vicinity of the wall surface of the low-dielectric-constant insulating film 3 having the opening 4 formed therein. In this case, the low-dielectric-constant insulating film 3 has hydrophobicity because it contains methyl groups. As shown in FIG. 1B, the etching product 5 composed of the atoms of the low-dielectric-constant insulating film 3 is deposited over the wiring layer 2 at the bottom of the opening 4 by processing the opening 4.

FIG. 2B shows the state after the plasma treatment with a gas containing hydrogen for removing the etching product 5 deposited over the bottom of the opening 4. In this case, the methyl groups near the wall surface of the low-dielectric-constant insulating film 3 are released by the plasma treatment with a gas containing hydrogen. Therefore, silanol groups are increased by hydrogen, and silanol groups are formed in place of the released methyl groups. As a result, the vicinity of the wall surface of the low-dielectric-constant insulating film 3 has hydrophilicity, and thus the damage layer 6 is formed by water absorption and oxidation. When a barrier metal is formed over the damage layer 6 in a subsequent step, the barrier metal is oxidized. The oxidation of the barrier metal causes a decrease in barrier property, diffusion of Cu atoms, which constitute the plug, into the low-dielectric-constant insulating film 3, and the occurrence of voids in the plug. The void produced causes disconnection of wiring. Thus, when the damage layer 6 is formed, reliability is decreased.

FIG. 2C shows the state after a plasma treatment with a gas containing fluorocarbon after the plasma treatment with a gas containing hydrogen. In this case, the silanol groups bonded to the wall surface of the low-dielectric-constant insulating film 3 can be removed by the plasma treatment with a gas containing fluorocarbon. As a result, the damage layer 6 formed over the wall surface of the low-dielectric-constant insulating film 3 is removed.

Therefore, the plasma treatments with different types of gases can change the conditions of the wall surface of the low-dielectric-constant insulating film 3, thereby removing the etching product 5 and the damage layer 6 which lead to a decrease in reliability.

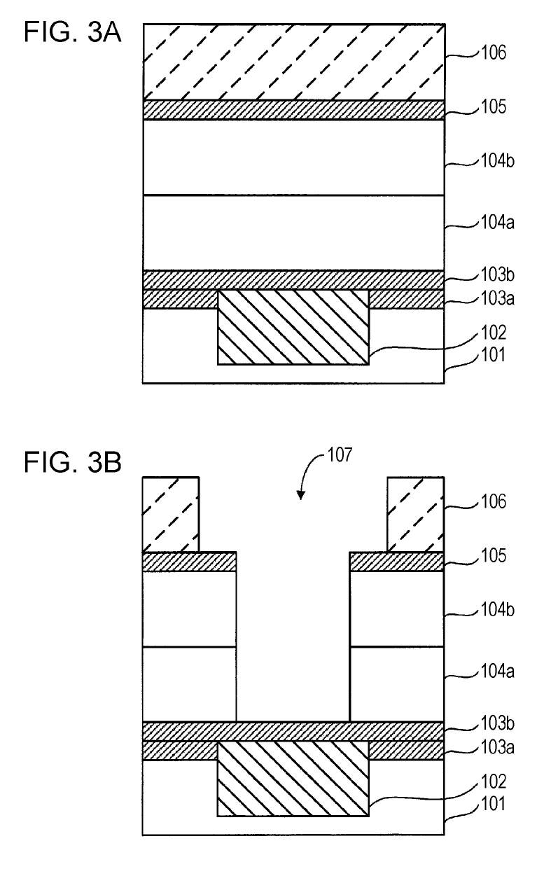

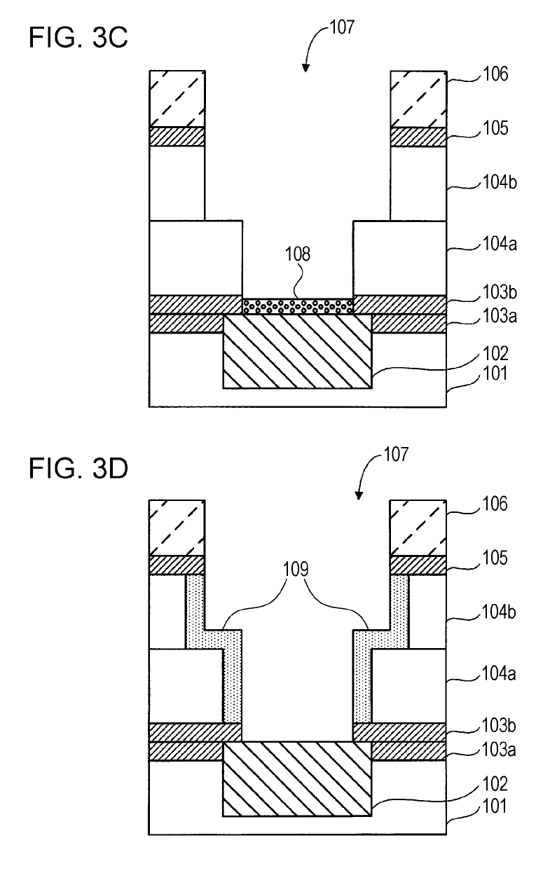

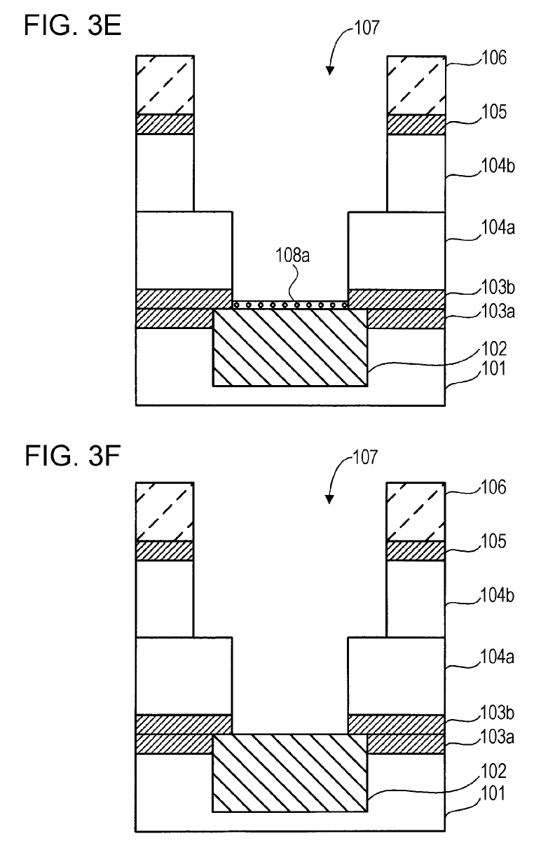

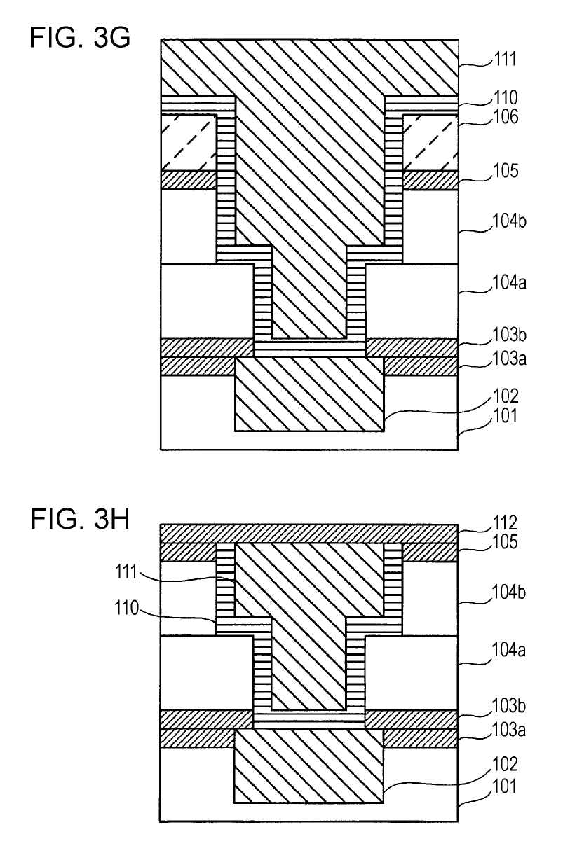

FIGS. 3A to 3H are sectional views showing a process of manufacturing a semiconductor device according to an embodiment of the present invention. However, this embodiment is only an example of a method of manufacturing a semiconductor device including a multilayer wiring structure. The manufacturing method and the procedures thereof or the materials used may be changed as long as the effect of resolving the problem to be resolved by the present invention can be achieved.

Although a process of forming wiring using a so-called dual damascene process is described herein, the present invention can be applied to a single damascene process.

As shown in FIG. 3A, first, a silicon carbide film 103a is formed as an etching stopper over a surface of a substrate 101. Then, a trench is formed in the silicon carbide film 103a and the substrate 101, and a Cu wiring layer 102 is formed in the trench.

Next, a silicon carbide film 103b is further formed over the silicon carbide film 103a and the Cu wiring layer 102. The thickness of the silicon carbide film 103b is, for example, 30 nm.

Then, insulating films 104a and 104b having a total thickness of 250 nm to 400 nm are formed over the silicon carbide film 103b. The insulating films 104a and 104b include, for example, Nano Clustering Silica (NCS: registered trade name) manufactured by Catalysts & Chemicals Industries Co., Ltd. which is porous silica. The NCS has a dielectric constant of about 2.3.

Then, a SiCOH film 105 is formed as a hard mask having a thickness of 20 nm to 40 nm over the interlayer insulating film 104b, and a silicon oxide film 106 is further formed to a thickness of 150 nm to 250 nm.

In order to form the via hole, the silicon oxide film 106 is etched to form an opening 107. The etching is stopped at the silicon carbide film 103b serving as the etching stopper. The etching is performed using, for example, a gas containing difluoromethane.

As shown in FIG. 3B, the silicon oxide film 106 is patterned for forming wiring.

As shown in FIG. 3C, the interlayer insulating film 104b is dry-etched and the silicon carbide film 103b at the bottom of the opening 107 is also etched using the patterned silicon oxide film 106 as a mask. The etching is performed using, for example, a gas containing CH₂F₂. In this step, an etching product 108 is formed over the Cu wiring layer 102 at the bottom of the opening 107.

A plasma treatment is performed using a gas containing hydrogen or ammonia. The conditions of the plasma treatment include 10% to 100% hydrogen gas, 90% to 0% nitrogen gas, a pressure of 15 mT to 250 mT, a voltage of 100 W to 300 W applied to a plasma generating electrode, and a treatment time of 3 seconds to 20 seconds. Even when a mixed gas of hydrogen and ammonia, a mixed gas of hydrogen and nitrogen, or a mixed gas of hydrogen and argon or helium is used as a gas in the plasma treatment, the same effect can be obtained. The dry etching of the interlayer insulating film 104b is preferably transferred to the plasma treatment for removing the etching product 108 without exposure to air.

In the plasma treatment with a gas containing hydrogen, methyl groups near the wall surfaces of the interlayer insulating films 104a and 104b are released, and silanol groups are bonded to the release positions. Therefore, the wall surfaces of the interlayer insulating films 104a and 104b have hydrophilicity, and thus water penetration and oxidation occur, thereby forming a damage layer 109 having a thickness of about 2 nm to 8 nm as shown in FIG. 3D.

In order to remove the damage layer 109, a plasma treatment is performed using, for example, a gas containing carbon tetrafluoride as a fluorocarbon gas. The conditions for the treatment include a flow rate of carbon tetrafluoride gas of 50 sccm to 200 sccm, a pressure of 15 mT to 50 mT, a voltage of 100 W to 300 W applied to a plasma generating electrode, and a treatment time of 3 seconds to 20 seconds. As the gas used in the plasma treatment, a single gas of carbon tetrafluoride or a mixed gas containing carbon tetrafluoride, trifluoromethane, and difluoromethane can be used. Even when a mixed gas of these gases and Ar or He is used, the same effect can be obtained. Also, a mixed gas of carbon tetrafluoride and carbon monoxide or methane is preferably used. Since the damage layer 109 is removed, the opening 107 is previously formed in a size determined in consideration of a removal amount so that a desired size can be achieved after the removal of the damage layer 109. In this case, the plasma treatment for removing the etching product 108 is preferably transferred to the plasma treatment for removing the damage layer 109 without exposure to air.

As shown in FIG. 3E, when the damage layer 109 is removed by the plasma treatment with a gas containing carbon tetrafluoride, another etching product 108a may be slightly formed over the Cu wiring layer 102 at the bottom of the opening 107.

In order to remove the etching product 108a, as shown in FIG. 3F, wet etching is performed with hydrofluoric acid or ammonium phosphate. This step is performed according to demand. The wet etching is performed within 2 hours to 3 hours after the formation of the etching product 108a, and preferably as early as possible after the formation of the etching product 108a.

Then, as shown in FIG. 3G, a tantalum film is deposited as a barrier metal film 110 having a thickness of 5 nm to 15 nm after the removal of the etching product 108a. When tantalum, titanium, tantalum nitride, or a laminated film thereof is used as a barrier metal, the same effect can be obtained. The barrier metal can be formed by, for example, sputtering, and particularly bias sputtering.

Then, a seed film including Cu (not shown) is deposited over the barrier metal film 110. Furthermore, a wiring layer 111 including Cu is deposited over the seed layer by, for example, plating.

After the deposition of the wiring layer 111, as shown in FIG. 3H, the silicon oxide film 106, the barrier metal film 110 and the wiring layer 111 above the SiCOH film 105 are removed by chemical mechanical polishing (CMP).

A silicon carbide film 112 is formed over the SiCOH film 105.

Then, a laminate is formed again on the silicon carbide film 112 as shown in FIG. 3A, and the steps shown in FIG. 3A to 3H are repeated to form a multilayer wiring structure having a desired number of layers.

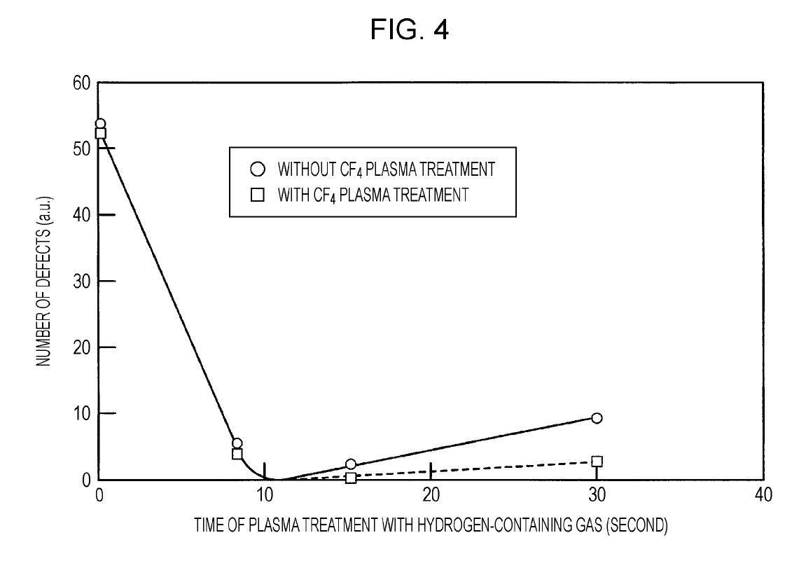

FIG. 4 shows a relation between the time of plasma treatment with a gas containing hydrogen and the number of defects in the plug in each of the above-described manufacturing method and a manufacturing method not including a plasma treatment with a gas containing carbon tetrafluoride. FIG. 4 shows both the case in which the plasma treatment with a gas containing carbon tetrafluoride is performed after the plasma treatment with a gas containing hydrogen and the case in which the plasma treatment with a gas containing carbon tetrafluoride is not performed.

In FIG. 4, the time of the plasma treatment with a gas containing hydrogen is shown in abscissa, and the number of defects in the plug is shown in ordinate. FIG. 4 shows the results of the number of defective convex pattern chains after allowing to stand at 200° C. for 1000 hours, the pattern chains each having a plug diameter of 100 nm and a wiring width of 5 μm.

First, description is made of the case in which the plasma treatment with a gas containing carbon tetrafluoride is not performed. The number of defects in the plug decreases as the time of the plasma treatment with a hydrogen-containing gas increases. In other words, the etching product 108 is possibly removed by the plasma treatment with a hydrogen-containing gas.

After the number of defects in the plug is minimized, the number of detects again increases with increases in the treatment time. Namely, it is thought that although the etching product 108 is removed by the plasma treatment with a hydrogen-containing gas to minimize the number of defects in the plug, the damage layer 109 is formed over the wall surfaces of the interlayer insulating films 104a and 104b to increase the number of defects in the plug.

Next, description is made of the case in which the plasma treatment with a gas containing carbon tetrafluoride is performed according to the embodiment. Like in the case in which the plasma treatment with a gas containing carbon tetrafluoride is not performed, the number of defects in the plug decreases as the time of the plasma treatment with a hydrogen-containing gas increases.

After the number of defects in the plug is minimized, the number of detects again increases. However, the rate of increase is low as compared with the case in which the plasma treatment with a gas containing carbon tetrafluoride is not performed. In other words, the etching product 108a and copper oxide are diminished at the bottom of the opening 107 by the plasma treatment with a gas containing carbon tetrafluoride, but the damage layer 109 formed by the plasma treatment with a hydrogen-containing gas is removed, thereby suppressing an increase in the number of defects in the plug wiring.

The graph of FIG. 4 indicates that in the embodiment, the etching product 108 formed over the Cu wiring layer 12 and the damage layer 109 formed over the wall surfaces of the interlayer insulating films 104a and 104b can be removed, thereby realizing a semiconductor device having a multilayer wiring structure with high reliability.

In this embodiment, a low-dielectric-constant insulating film is formed over a wiring layer, an opening is formed in the low-dielectric-constant insulating film, and a plasma treatment with a gas containing hydrogen or ammonia and a plasma treatment with a gas containing fluorocarbon are performed. Therefore, it is possible to provide a method of manufacturing a semiconductor device in which an increase in resistance and disconnection are prevented to improve reliability.

In addition, the present invention can be applied to the case in which a polyarylene film, a polyallyl ether film, a hydrogen silsesquioxane film, a methyl silsesquioxane film, a silicon carbide film, a porous silica film, or a mixed film or laminated film thereof is used as the low-dielectric-constant insulating film.

The foregoing is considered as illustrative only of the principles of the present invention. Further, since a number modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method of manufacturing a semiconductor device comprising:
forming an interlayer insulating film over a wiring layer;
forming an opening exposing a surface of the wiring layer in the interlayer insulating film;
performing a first plasma treatment to the wiring layer in the opening using a gas including hydrogen or ammonia; and
performing a second plasma treatment with a gas including fluorocarbon after the first plasma treatment.

2. The method according to claim 1, wherein the interlayer insulating film includes an insulating film having a first dielectric constant value lower than a second dielectric constant value of a silicon oxide film.

3. The method according to claim 1, wherein the opening is formed by etching with a gas including difluoromethane.

4. The method according to claim 1, wherein the interlayer insulating film includes at least one of a polyarylene film, a polyallyl ether film, a hydrogen silsesquioxane film, a methyl silsesquioxane film, a silicon carbide film, a porous silica film, a mixed film thereof, and laminated film thereof.

5. The method according to claim 1, wherein the interlayer insulating film includes a methyl group.

6. The method according to claim 4, wherein the porous silica film has a dielectric constant value of 2.5 or less.

7. The method according to claim 1, wherein the fluorocarbon is carbon tetrafluoride.

8. The method according to claim 1, further comprising:
forming a barrier metal film in the opening after the second plasma treatment.

9. The method according to claim 8, wherein the barrier metal film includes at least one of a tantalum film, a tantalum nitride film, a titanium film, and a laminated structure thereof.

10. The method according to claim 9, wherein the barrier metal film is formed by sputtering.

11. The method according to claim 8, further comprising:
wet-etching the surface of the wiring layer after the second plasma treatment and before forming the barrier metal film.

12. The method according to claim 11, wherein the wet etching is performed with a chemical liquid including at least one of ammonium phosphate and hydrofluoric acid.

13. The method according to claim 1, wherein the gas including fluorocarbon further includes at least one of carbon monoxide and methane.

14. The method according to claim 1, wherein the gas including fluorocarbon further includes at least one of a trifluoromethane gas and a difluoromethane gas.

15. The method according to claim 1, wherein the wiring layer includes Cu.

16. A method of manufacturing a semiconductor device comprising:
forming an interlayer insulating film over a wiring layer including Cu;
etching the interlayer insulating film to form an opening exposing the wiring layer;
performing a first plasma treatment to the wiring layer exposed in the opening using a gas including a reducing gas; and
performing a second plasma treatment to the insulating film having the opening with a gas including fluorocarbon after the first plasma treatment.

17. The method according to claim 16, wherein the interlayer insulating film includes an insulating film having a first dielectric constant value lower than a second dielectric constant value of a silicon oxide film.

18. The method according to claim 16, further comprising:
forming a silicon carbide film over the wiring layer before forming the interlayer insulating film,
etching the silicon carbide film using an etching gas including difluoromethane after etching the interlayer insulating film.
